(19) United States
(12) Patent Application Publication
(10) Pub. No.: US 2012/0061802 A1
(43) Pub. Date: Mar. 15, 2012

(54) BIPOLAR JUNCTION TRANSISTOR

(76) Inventors: Gareth NICHOLAS, Great Milton (GB); Benjamin James Hadwen, Oxford (GB); Sunay Shah, Oxford (GB)

(21) Appl. No.: 12/878,062

(22) Filed: Sep. 9, 2010

(51) Int. Cl. H01L 29/73

(52) U.S. Cl. 257/592; 257/E29.174

(57) ABSTRACT

A bipolar junction transistor includes a semiconductor island on an insulating substrate; an emitter and at least one of a collector and sub collector within the semiconductor island, the emitter and the at least one of the collector and the sub collector being of a first conductivity type; a base within the semiconductor island separating the emitter and the at least one of the collector and the sub collector, the base being of a second conductivity type; a base contact region within the semiconductor island, the base contact region being of the second conductivity type; and a connecting base region adjacent the base within the semiconductor island and connecting the base to the base contact region while not directly contacting the emitter, the connecting base region being of the second conductivity type with a doping concentration less than a doping concentration of the base contact region.

### TECHNICAL FIELD

The present invention relates generally to bipolar junction transistors (BJTs), and more specifically to lateral bipolar junction transistors that may be fabricated in the manufacture of the display substrate of an active matrix liquid crystal display (AMLCD). Such lateral bipolar junction transistors enable analogue circuits, such as bandgap references or logarithmic converters that are difficult to achieve with thin film transistors (TFTs). The BJTs may also enable certain high frequency applications, such as RF communications.

### BACKGROUND ART

FIG. 1 shows an AMLCD substrate 100. In the display pixel matrix 102, TFTs are located next to each pixel, or sub-pixel in the case of a colour display, to control the level of light emitted. TFTs are also widely used in the display gate and source drivers 104 and 106 respectively, and may also be employed in a sensor driver circuit 108. The AMLCD further includes a display controller 110 for providing appropriate control of the gate and source drivers 104, 106, etc. In addition, the AMLCD includes a backlight 112 controlled by a backlight controller 114. Sensor output circuitry 116 is coupled to the sensor driver circuit 108. Many products utilise such AMLCDs (e.g. mobile phones and personal digital assistants (PDAs)).

The TFT is a variant of the metal-oxide-semiconductor field effect transistor (MOSFET), which is an electronic device consisting of two semiconductor diodes placed back to back and a capacitor formed between the semiconductor and a gate electrode that controls the current flow between the diodes. The structure of semiconductor diodes and transistors is well known [Y. Taur and T. K. Ning, “Fundamentals of Modern VLSI Devices,” pp. 29-31 & 112-113, Cambridge University Press, 1998] and will not be described here. The difference between a TFT and a conventional MOSFET is that in a TFT the semiconductor takes the form of a thin film placed on an insulating substrate, rather than the entire substrate being comprised of the semiconductor material.

FIG. 2 shows a typical TFT, with the top-gate configuration (gate electrode 202 positioned above the semiconductor). The structure would typically be covered with a dielectric (e.g. SiO₂) that has been omitted from the diagram for clarity. The fabrication processes for the various types of TFTs are well known but are outlined here, since they are relevant to the invention. A base coat insulator 204 (typically SiO₂) is deposited on the substrate (not shown; typically glass, but other materials including quartz and plastics may be used). If the final device is to incorporate a gate electrode below the channel, the gate material (usually a metal such as TiN, TaN, W or Mo, or sometimes poly Si) is deposited and patterned, followed by the deposition of a thin insulator layer (typically a few tens of nm of SiO₂). The semiconductor 206 (most likely poly Si) is deposited and patterned. It is usual for each TFT to be created in an individual semiconductor island 206 on the base coat insulator 204. Because each TFT is thus isolated, problems such as cross talk between adjacent devices are alleviated.

Lithography is the most common technique for patterning the semiconductor and other layers in the fabrication of a TFT. A light-sensitive chemical known as a photoresist is spun onto a deposited layer and then exposed to ultraviolet light whilst covered with a photo mask, so that only certain defined regions of the photo resist may react with the light. The resist is then developed so that either the regions that were exposed or those that weren't are removed (depending on whether the resist used is “positive” or “negative”). The deposited layer may then be etched; the regions still covered by photoresist are protected from this process. The remaining resist is then removed. Since the fabrication of TFTs requires several such masking steps, all subsequent masks must be precisely aligned to the first. There will however always be unavoidable small errors in alignment, the magnitude of which depends on the accuracy of the mask aligner used. These errors must be accounted for in the design of the TFT.

At this point, a treatment such as laser annealing may be used to crystallise the semiconductor if it was deposited in the amorphous state, and the semiconductor may be doped by ion implantation or diffusion. If the TFT is to incorporate a gate electrode 202 above the channel, a thin insulator layer and gate material (gate insulator 208) are then deposited and patterned. The source and drain regions are formed (typically by ion implantation) so that they are heavily doped with an opposite polarity to the semiconductor material between them. For top-gate TFTs, the presence of the gate electrode serves to block implanted ions, so that they are only introduced to the semiconductor adjacent to it. This is known as a self-aligned implant. For non self-aligned implants, a developed photoresist may be relied upon to block the dopant ions where they are not required.

In a complementary process both n-channel TFTs (nTFTs) and p-channel (pTFTs) are created, so that at least two doping steps are required. For example, the nTFT source and drain regions may be formed by a phosphor (n-type) implant whilst the pTFTs are masked by photoresist. The pTFT source and drain regions may then be formed by a boron (p-type) implant with the nTFTs masked.

The TFT fabrication is completed by opening holes in a deposited dielectric (typically SiO₂ or SiNₓ) and depositing and patterning metal contacts for the source, drain electrodes 210 and gate electrode 202. The formation of these contacts necessarily requires a certain minimum area of semiconductor, referred to herein as contact regions.

Because the substrate used for the TFT backplane is usually glass, there is a requirement to keep temperatures relatively low (below approximately 600° C.) throughout the fabrication process in order to minimise shrinkage and melting. Alternative substrate materials such as plastic have even more stringent maximum temperature limitations.

TFTs are well suited to logic applications because of their low standby power dissipation. The frequency at which they can be switched between the on and off states is limited however. Mass production requirements such as cost and yield limit the minimum achievable gate length and gate oxide thickness. These factors, combined with the relatively low mobility of charge carriers in typical thin film semiconductors (e.g. amorphous Si, poly Si, metal oxide) mean that operating frequencies are generally limited to tens of MHz.

In common with all semiconductor devices, the electrical characteristics of TFTs vary with temperature. This can be problematic, since an AMLCD is typically expected to operate within a temperature range of −30° C. to 70° C. A bandgap reference circuit can help to overcome these difficulties by generating a reference voltage that is independent of temperature. Unfortunately, the electrical properties of TFTs do not permit a simple implementation of a bandgap reference.

The bipolar junction transistor (BJT) is an alternative device that has different strengths and weaknesses as compared to the MOSFET. A cross-section through a BJT is shown in FIG. 3. The device is of the npn type, in which a p-type doped base 304 region is sandwiched between n-type emitter 302 and collector 306 regions. A bipolar transistor therefore consists of two p-n junction diodes placed back-to-back. In normal operation, the emitter-base diode is forward biased (positive voltage applied to the base relative to the emitter), which for a npn device results in holes being injected from base to emitter and electrons being injected from emitter to base. In normal operation the base-collector junction is reverse biased (positive voltage applied to the collector relative to the base), so that electrons injected into the base may continue to the collector, giving rise to a collector current, I_{C}. The holes injected from the base to the emitter give rise to a base current, I_{B}.

A basic objective of BJT design is to achieve a collector current significantly larger than the base current. DC current gain, β, is an important measure of device efficiency and is defined as β=I_{C}/I_{B}. Because the emitter typically has a much higher concentration of doping than the base, many more electrons are injected across the emitter-base junction than holes travelling in the opposite direction. This gives rise to a larger collector current than base current, and a gain that may be significantly greater than unity (β of 100 is typical).

A proportion of the electrons injected from the emitter will not result in collector current because of recombination with holes in the base region. Recombination of carriers therefore has the effect of degrading the current gain. The amount of recombination that occurs may be reduced by making the base region as short as possible, so that electrons traverse the region quickly.

The BJT may be switched between the on and off states by altering the potential of the base region. In the off state, the base contact is held at the same potential as the emitter contact so that there is no current flow across the emitter-base junction. Ignoring the small reverse bias leakage current across the base-collector junction, I_{C} and I_{B} are effectively zero. Increasing the potential on the base contact relative to the emitter (whilst keeping it below the potential of the collector) turns the transistor on, and causes current to flow.

Compared to the MOSFET, the BJT has two key advantages. Firstly, the lack of a conductor-insulator-semiconductor gate stack results in the BJT having a much smaller capacitance than an equivalently sized MOSFET. This means that significantly higher switching speeds are achievable when using BJTs. Cut-off frequencies greater than 100 GHz are possible for state of the art devices, making the BJT an important device whenever very high speed digital circuit applications are required.

The second advantage of the BJT is that the base-emitter voltage has a negative temperature coefficient. As the ambient temperature increases, the base-emitter voltage required to maintain a given current is reduced. This is in contrast to a MOSFET, where an increase in temperature means that a larger gate voltage is required to maintain drain current. This characteristic of the BJT can be exploited in bandgap reference circuits by employing two such devices with different widths and driving a constant current through them. Whilst the base-emitter voltage of a single device decreases in response to an increase in temperature, the difference between the base-emitter voltages of the two devices increases (it has a positive temperature coefficient). By selecting appropriate device widths and current conditions, the sum of this difference and one of the base-emitter voltages can be made to be independent of temperature.

The main disadvantage of the BJT compared to the MOSFET is higher power consumption. In contrast to the MOSFET, which typically only consumes a significant amount of power during switching between states, the BJT may consume power during the entire time that it is in the on-state. This is due to the undesirable base current that flows in the device. For this reason, it is generally not desirable to construct entire integrated circuits using only BJTs. Instead, BJTs find application in BiCMOS circuits, which use both MOSFETs and BJTs to complement each other.

The major difficulty for BiCMOS circuitry is that it requires that MOSFETs and BJTs are fabricated together in a process flow. Typically, this requires significantly more complex fabrication than is the case for a single device type, increasing cost. For the case of an AMLCD, it is desirable to fabricate BJTs alongside TFTs whilst adding as few additional process steps to the fabrication process as possible.

The BJT shown in FIG. 3 is of the vertical type, in which the majority of current flow between the emitter and collector occurs in the y direction. This is the preferred architecture, because the emitter-base and base-collector junctions may be formed by ion implantation or diffusion of dopants into the semiconductor. This enables the depth of various regions to be tightly controlled by setting the implantation energy, giving short base lengths with good reproducibility. In addition, the conduction carriers are not in close proximity to interfaces between materials, which typically degrade mobility and enhance the likelihood of recombination. The total height of the structure will be on the order of hundreds of nm. This makes the vertical BJT unsuitable for inclusion in a thin film process, in which the semiconductor thickness is typically less than 100 nm.

U.S. Pat. No. 5,629,554 (H. Maas et al.; issued May 13, 1997) describes a vertical BJT that can be fabricated in a thin film process. The emitter is included as an additional semiconductor layer that is placed on top of the layer containing the base and collector. This structure retains many of the advantages of a vertical BJT, but would add a great degree of additional complexity and expense to a conventional TFT fabrication process, which only includes one semiconductor deposition step.

FIG. 4 is a cross-section of a lateral BJT. The emitter 402, base 404 and collector 406 lie laterally adjacent to one another (i.e., in a direction generally parallel to the substrate), with the doping in each region extending throughout the thickness of the semiconductor 414. The current flow between emitter 402 and collector 406 occurs largely in the x direction. The emitter 402, base 404 and collector 406 are in turn connected to an emitter electrode 408, base electrode 410 and collector electrode 412, respectively. The structure of FIG. 4 has greater compatibility with a TFT fabrication process. The disadvantage is that the regions must be positioned using lithography rather than controlling the depth of dopants with ion implantation or diffusion. This makes it difficult to realise a short base, particularly since a contact to this region must be included for connecting to the base electrode 410. In addition, conduction carriers are in close proximity to two interfaces between semiconductor 414 and insulator 416 (at the top and bottom of the film), which results in an increase in recombination.

In order to reduce the base length as far as possible, the electrical contact to this region may be placed to one side of the device. As is shown in plan view in FIG. 5, the base contact region 508 is offset laterally from the emitter 502, base 504 and collector 506. However, this has the negative effect of increasing the base resistance, which degrades the high frequency performance. In addition, the voltage drop across the base region means that the effectiveness of the base 504 in controlling the collector current decreases with distance from the base contact region 308. This results in collector current that does not scale linearly with width (y direction in FIG. 5). Wide devices (10 μm or more) may have significantly degraded performance.

The doping in the base 504 may be increased to compensate for these problems. However, there are limits on how far the doping may be increased. The collector 506 is typically quite highly doped. A highly doped base region thus creates a p-n junction in which both sides are highly doped, resulting in small depletion regions and large junction capacitance, which degrades high frequency performance. Small depletion regions also give rise to large reverse junction leakage current and hot carrier degradation concerns, particularly for disordered films such as a-Si or poly-Si. In addition, theory predicts a linear relationship between collector current density and base sheet resistance, due to the decrease in emitter efficiency [Y. Taur and T. K. Ning, “Fundamentals of Modern VLSI Devices,” pp. 356-357, Cambridge University Press, 1998]. Both of these factors degrade the current gain of the device.

U.S. Pat. No. 6,174,779 (T. Shino et al.; issued Jan. 16, 2001) describes a lateral

BJT which overcomes some of the difficulties associated with relying solely on lithography and ion implantation to create the device. Rather than relying on accurately aligning two or more masks, reproducibility in the fabrication process is ensured by exploiting the diffusion of dopants during annealing. Very high temperatures are required for dopant diffusion to take place, however (1000 to 1100° C. is typical). This is incompatible with device fabrication on a plastic or glass substrate.

The series resistance problems encountered for lateral BJTs with an offset base contact region may be mitigated by including a second offset base contact region on the opposite side of the device. However, the second base contact region does not completely remove the issue of non-linear collector current scaling with device width. In this case it is the base region in the centre of the device that is least effective in controlling collector current. Where large currents are required, it may be better to use multiple narrow BJTs in parallel, rather than a single wide device.

In order to improve the performance of a lateral BJT, the collector may be split into two regions with different doping concentrations, namely a collector 606 and a sub collector 610 as shown in FIG. 6. In order to minimise series resistance, the sub collector 610 is highly doped. It is not desirable for the collector 606 region that contacts the base 604 to be doped to such a high level, however. This is due to the aforementioned problems that can arise when small depletion regions form between the base and collector, and increased junction capacitance. The collector 606 may also be made wider than the emitter 602, in order to increase the likelihood of conduction carriers being collected, rather than recombining in the base 604.

JP H04-291926 A (N. Higaki et al.; published Oct. 16, 1992) discloses a thin film lateral BJT which has two base contact regions, one on each side of the device, and distinct collector 606 and sub-collector 610 regions as shown in FIG. 6. It would be possible to fabricate such a device alongside TFTs without requiring a significant degree of additional process complexity. There is a large degree of overlap or direct contact between the connecting base regions 612 and the emitter 602 along the x direction, however. Because the emitter-base junction is typically forward biased, it is desirable to minimise the area of the emitter-base junction. A large junction of this type will result in a large current flowing between the base and emitter, degrading the current gain of the device.

Although the prior art therefore describes techniques for fabricating BJTs alongside MOSFETs, the majority of these are unsuitable for a thin film fabrication process without adding a large degree of complexity, or exceeding maximum temperatures for an AMLCD process. The prior art also describes a lateral BJT that could be fabricated alongside TFTs with minimal extra expense. This prior art device suffers from poor current gain however, due to large undesirable currents between the base and emitter.

### SUMMARY OF INVENTION

An aspect of the invention is to employ base contact regions on one or both sides of a lateral BJT, and moreover to offset them towards the collector and/or sub collector using connecting base regions so that there is no direct contact, i.e. overlap, between the connecting base regions and the emitter. This greatly reduces the current flowing between the base and emitter when the junction is forward biased in normal operation, improving the current gain of the device.

The lateral BJT according to an exemplary embodiment includes:
An island of semiconductor material positioned on an insulating substrate.
An emitter and collector and/or sub collector of a first conductivity type within the semiconductor island, on either side of:
A base of a second conductivity type within the semiconductor island.
At least one connecting base region within the semiconductor island.

A first connecting base region is positioned adjacent to the base and the collector and/or sub collector and is of the same conductivity type and doping concentration as the base. A second connecting base region is positioned adjacent to the base and the collector and/or sub collector on the opposite side of the device to the first connecting base region, and is of the same conductivity type and doping concentration as the base.
A base contact region for each connecting base region. Each base contact region is placed within the semiconductor island adjacent to one of the connecting base regions and is of the second conductivity type, with a doping concentration that is significantly higher than that of the connecting base region.

The present invention overcomes the problems associated with the prior art as discussed above by virtue of the removal of direct contact, or overlap, between the connecting base regions and the emitter. This reduces the size of the forward biased p-n junction that exists between the emitter and the base and connecting base regions.

In common with JP H04-291926 this invention can be fabricated in a conventional TFT process flow without any additional complexity. A significant advantage over the prior art is the restriction on current flow between the base and emitter that this arrangement gives. A smaller base current results in a larger DC current gain and a more efficient device, giving improved performance for analogue applications.

According to an aspect of the invention, a bipolar junction transistor, is provided that includes a semiconductor island on an insulating substrate; an emitter and at least one of a collector and sub collector within the semiconductor island, the emitter and the at least one of the collector and the sub collector being of a first conductivity type; a base within the semiconductor island separating the emitter and the at least one of the collector and the sub collector, the base being of a second conductivity type; a base contact region within the semiconductor island, the base contact region being of the second conductivity type; and a connecting base region adjacent the base within the semiconductor island and connecting the base to the base contact region while not directly contacting the emitter, the connecting base region being of the second conductivity type with a doping concentration less than a doping concentration of the base contact region.

According to another aspect, the base and the connecting base region have an equal doping concentration.

In accordance with another aspect, the sub collector has a doping concentration greater than a doping concentration of the base and equal to a doping concentration of the emitter.

According to yet another aspect, the connecting base region does not directly contact the at least one of the collector and the sub collector.

According to still another aspect, the connecting base region does directly contact the at least one of the collector and the sub collector.

In accordance with still another aspect, the transistor includes a second base contact region and a second connecting base region adjacent the base within the semiconductor island, and wherein the second connecting base region connects the base to the second base contact region while not directly contacting the emitter.

In yet another aspect, the base contact region and the second base contact region are adjacent opposite sides of the base.

According to another aspect, the collector is positioned between the base and the sub collector, and a doping concentration of the collector is less than a doping concentration of the emitter and a doping concentration of the sub collector.

According to another aspect, the connecting base region does not contact the sub collector.

In yet another aspect, a width of the at least one of the collector and the sub collector adjacent the base is greater than a corresponding width of the emitter.

According to still another aspect, the first conductivity type is n-type and the second conductivity type is p-type.

According to another aspect, the first conductivity type is p-type and the second conductivity type is n-type.

In still another aspect, a doping concentration of the base contact region is at least an order of magnitude higher than a doping concentration of the connecting base region.

According to another aspect, the semiconductor island comprises a thin film semiconductor.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF DRAWINGS

In the annexed drawings, like references indicate like parts or features:

FIG. 1 shows prior art: an AMLCD.

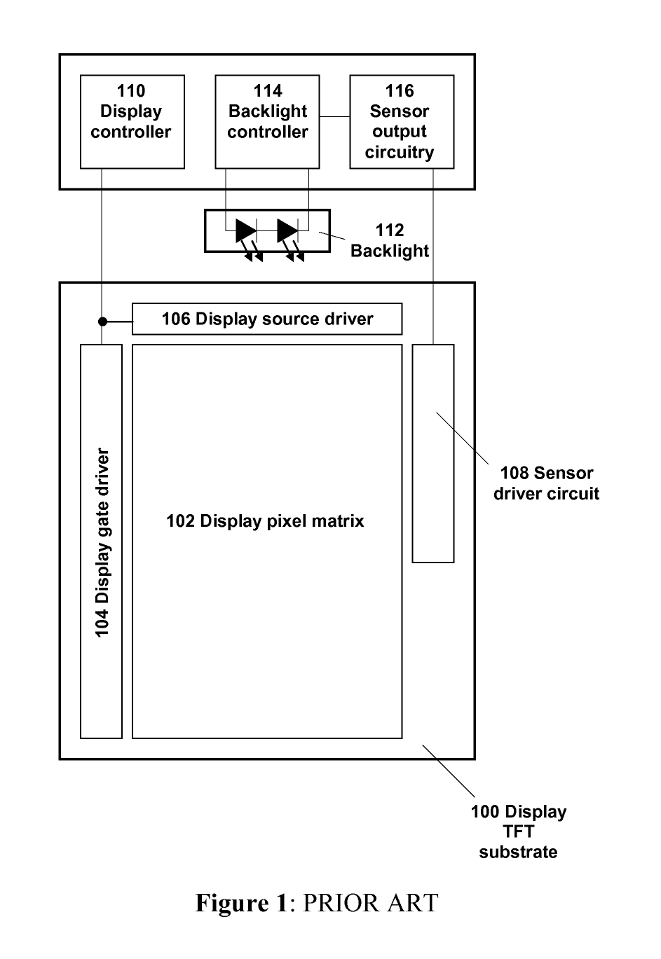

FIG. 2 shows prior art: a typical TFT with the top-gate configuration.

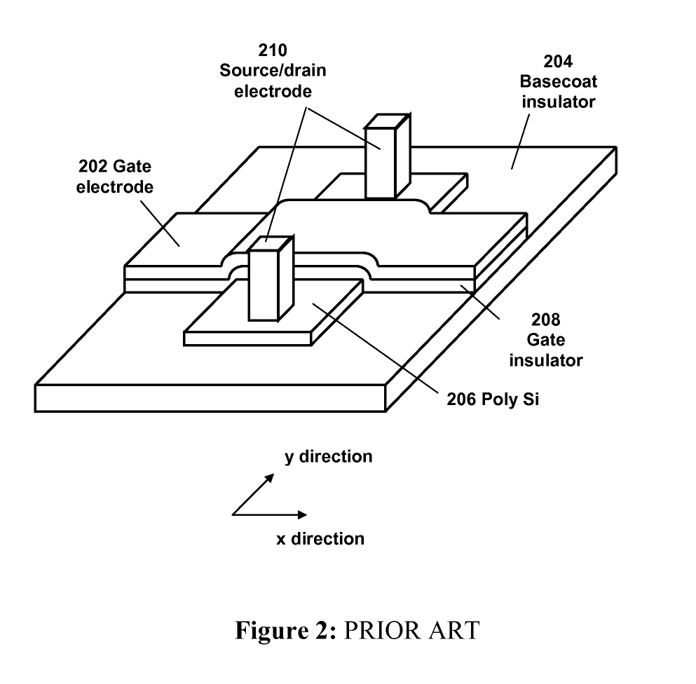

FIG. 3 shows prior art: a cross-section through a vertical BJT.

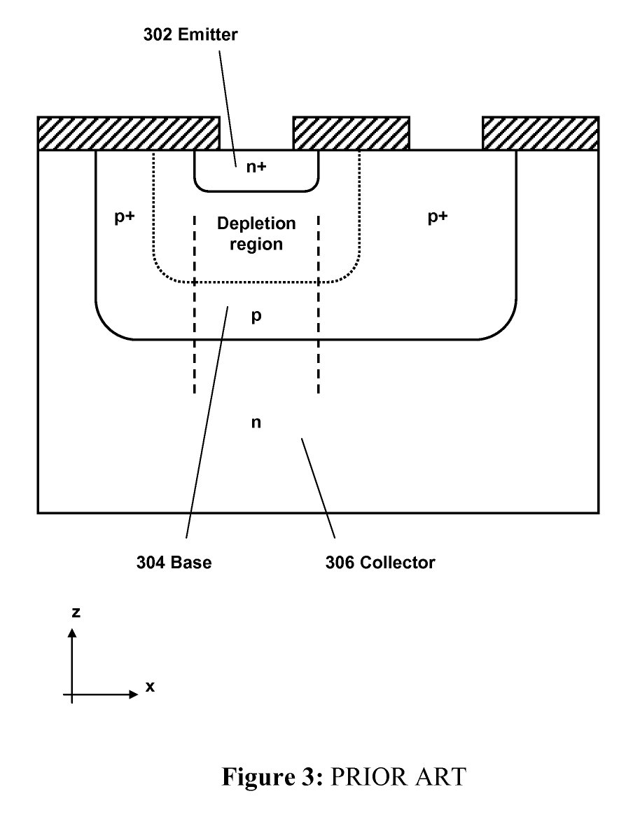

FIG. 4 shows prior art: a cross-section through a lateral BJT.

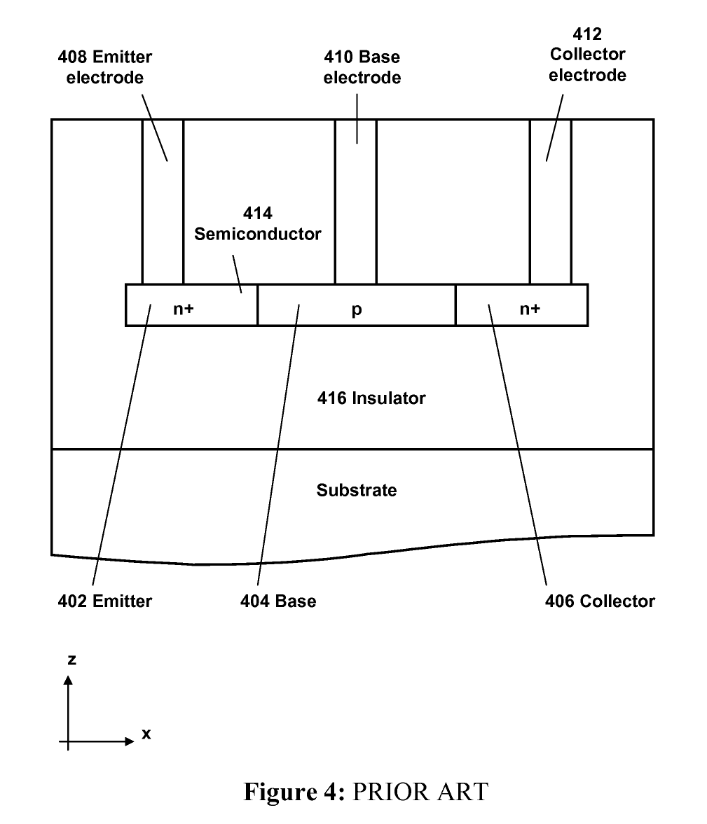

FIG. 5 shows prior art: a plan view of a lateral BJT with single base contact.

FIG. 6 shows prior art: a plan view of a lateral BJT with two base contacts.

FIG. 7 shows in plan view the first embodiment of the invention.

FIG. 8 shows in plan view the second embodiment of the invention.

FIG. 9 shows in plan view the third embodiment of the invention.

FIG. 10 shows in plan view the fourth embodiment of the invention.

### DESCRIPTION OF REFERENCE NUMERALS

100 Display TFT substrate
102 Display pixel matrix
104 Display gate driver
106 Display source driver
108 Sensor driver circuit
110 Display controller
112 Backlight
114 Backlight controller
116 Sensor output circuitry
202 Gate electrode
204 Basecoat insulator
206 Poly Si
208 Gate insulator
210 Source/drain electrode
302 Emitter
304 Base
306 Collector
402 Emitter
404 Base
406 Collector
408 Emitter Electrode
410 Base Electrode
412 Collector Electrode
414 Semiconductor
416 Insulator
502 Emitter
504 Base
506 Collector
508 Base contact region
602 Emitter
604 Base
606 Collector
608 Base contact region
610 Sub collector
612 Connecting base region
701 Semiconductor island
702 Emitter
704 Base
708 Base contact region
710 Sub collector
712 Connecting base region
808 Base contact region
812 Connecting base region
906 Collector

### DETAILED DESCRIPTION OF INVENTION

A first embodiment of the present invention provides a thin film lateral BJT with a single base contact region positioned in such a way as to minimise the current flow from base to emitter.

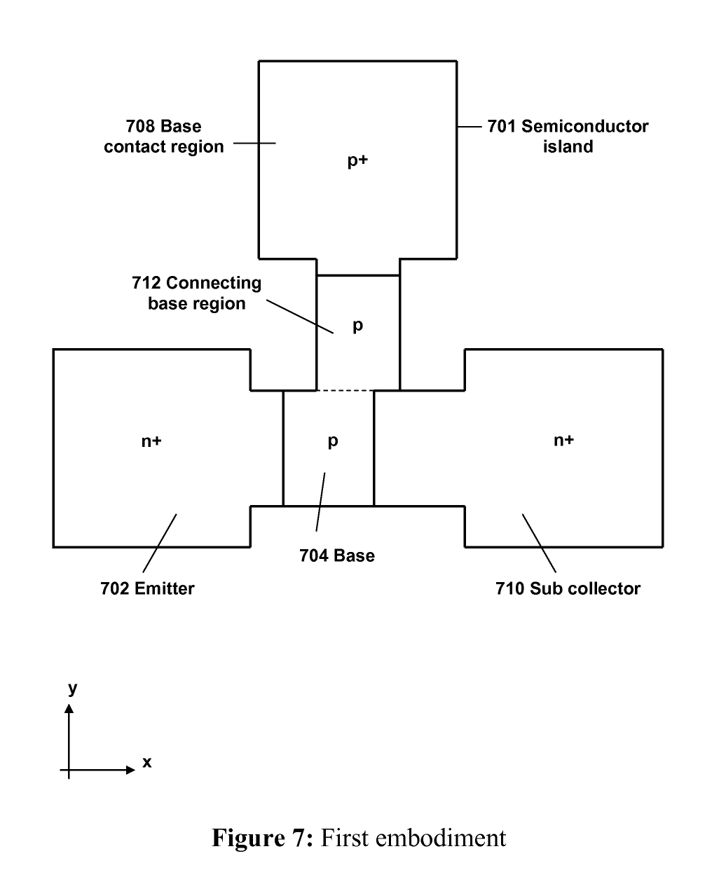

FIG. 7 illustrates the embodiment in plan view for the case of an npn BJT, but the invention applies equally to a pnp device. The BJT includes an island 701 of thin film semiconductor (most likely Si: either amorphous, polycrystalline or crystalline) positioned on top of an insulating substrate such as SiO₂, SiNₓ on glass or plastic (not shown).

The semiconductor island 701 includes an emitter 702, base 704, base contact region 708, sub collector 710 and connecting base region 712. The emitter 702 and sub-collector 710 regions are heavily doped (approximately 10¹⁹-10²¹ cm⁻³) with a first conductivity type (e.g., n-type) and are separated by the base 704, which is doped with a second conductivity type (e.g., p-type). Typical n-type dopants for Si are arsenic or phosphor. Typical p-type dopants are boron or gallium. The doping concentration in the emitter 702 and sub collector 710 is equal, and is greater than the doping concentration in the base 704, which is approximately 10¹⁶-10¹⁸ cm⁻³. The connecting base region 712 is positioned adjacent to the base 704 and sub collector 710 and connects the base 704 to the base contact region 708. The connecting base region 712 is doped with the second conductivity type and has a doping concentration which is equal to that of the base 704. The base contact region 708 represents a certain minimum area of semiconductor where electrical contact to the base 704 will be placed, and is positioned adjacent to the connecting base region 712 so that it does not contact the other regions (i.e., the emitter 702, base 704 and sub collector 710). The base contact region 708 is doped with the second conductivity type and a concentration that is at least an order of magnitude higher than the base 704 and connecting base region 712.

Notably, the connecting base region 712 is formed so as not to directly contact the emitter 702. As a result, the area of the p-n junction formed between regions of opposite conductivity types is minimised in size. This has the effect of reducing the current flow that can occur between the emitter 702 and base contact region 708.

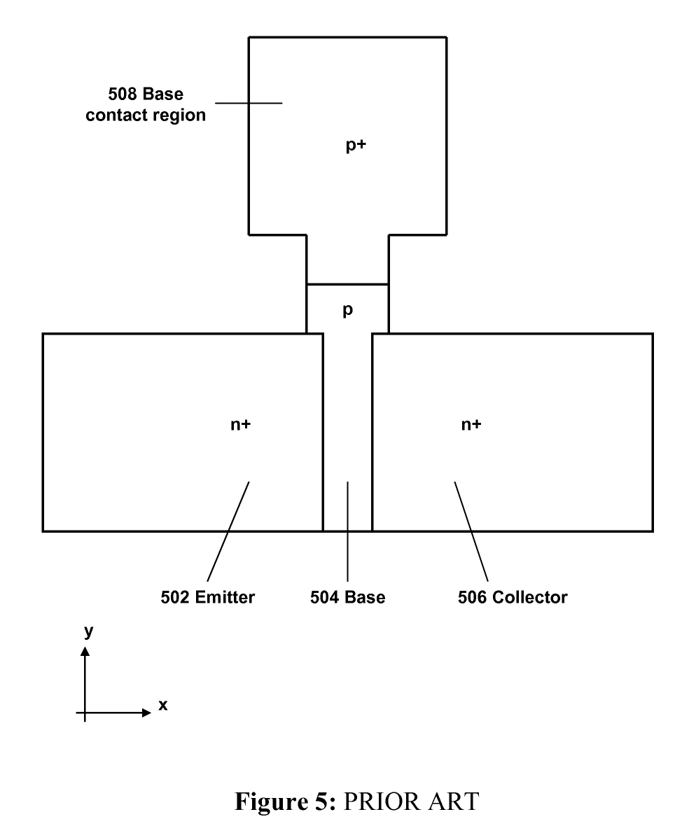

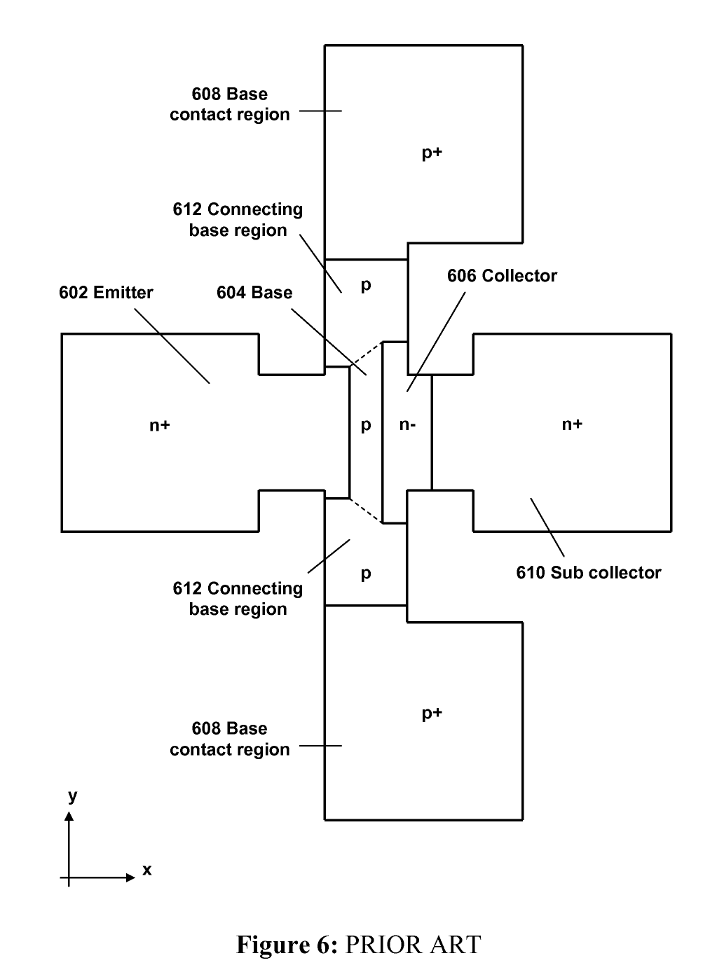

An advantage of this embodiment over the prior art such as that shown in FIGS. 5 and 6 is that the reduced current flow between the emitter 702 and the base contact region 708 and connecting base region 712 improves the efficiency of the device and improves performance for analogue applications.

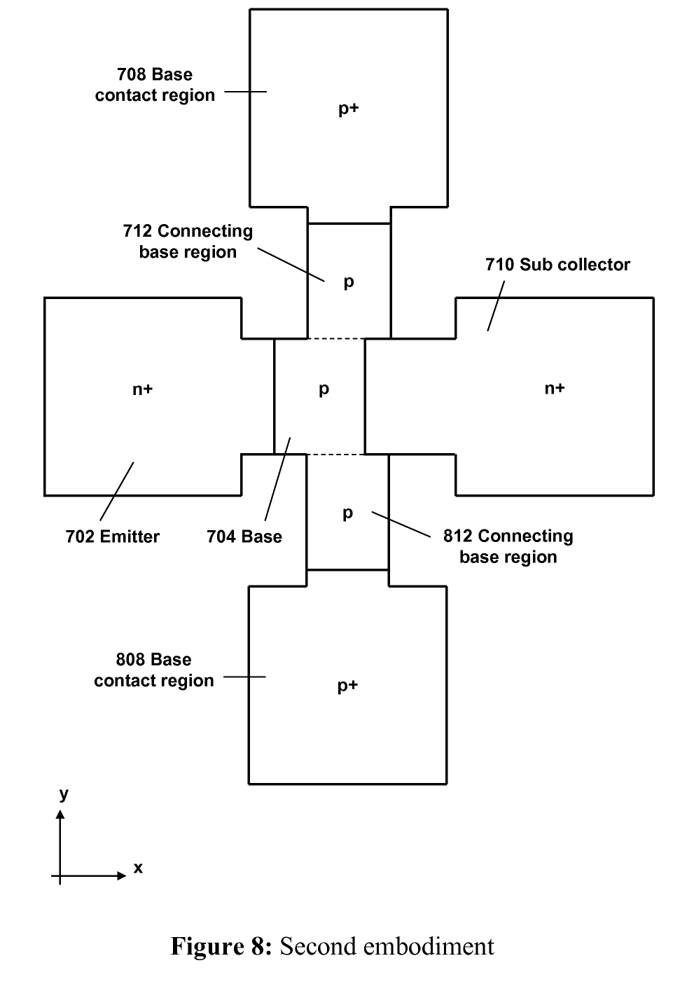

In the second embodiment of the invention, the BJT is formed as described in the first embodiment, but with the addition of a second base contact region, as shown in FIG. 8. More specifically, an additional connecting base region 812 is positioned on the side of the base 704 opposite the connecting base region 712. The connecting base region 812 contacts the base 704 and the sub collector 710 regions in the same way as the connecting base region 712 except on the opposite side of the base 704. Namely, the connecting base region 812 is patterned so as not to directly contact or overlap the emitter 702. A second base contact region 808 is positioned adjacent to the second connecting base region 812 so as to thereby be connected to the base 704. Like the base contact region 708, the base contact region 808 is formed so as not to directly contact any of the other regions, i.e., the emitter 702, base 704 or sub collector 710. The doping conductivity type and concentration of the additional connecting base region 812 and base contact region 808 are the same as those of the connecting base region 712 and base contact region 708 as described in the first embodiment.

This embodiment preserves the advantage of the first embodiment. The addition of a second electrical contact to the base 704 via the second base contact region 808 reduces the losses associated with base series resistance, and further improves the performance of the device.

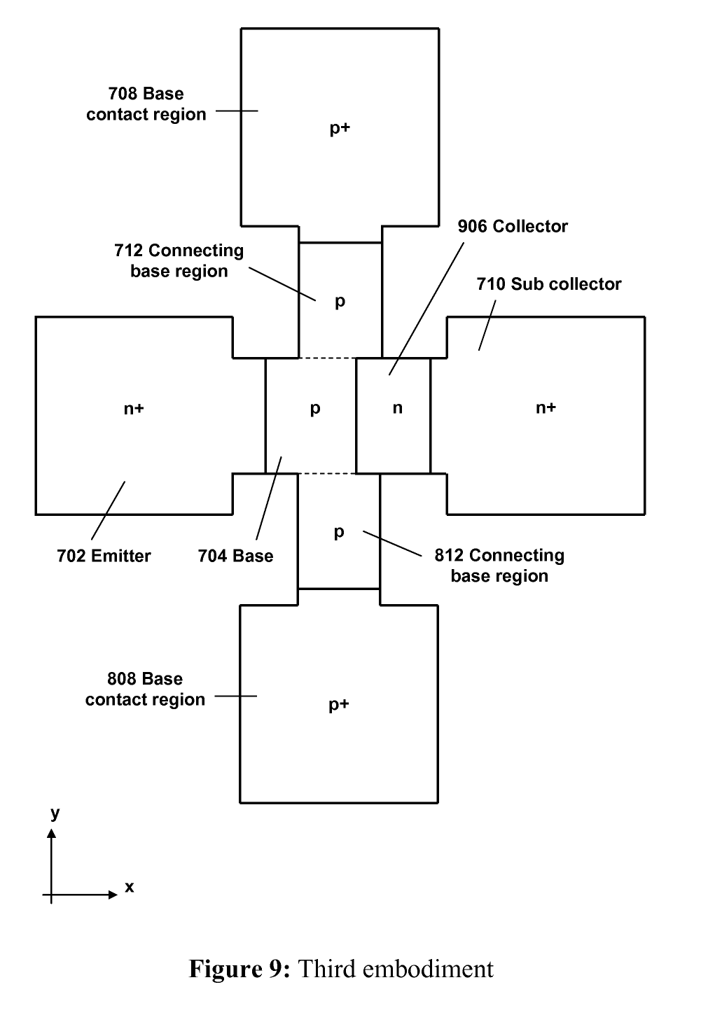

In the third embodiment of the invention, the BJT is formed as described in either of the first two embodiments, except that a collector 906 of the first conductivity type is positioned between the base 704 and sub collector 710 as shown in FIG. 9. The doping concentration of the collector 906 is less than that of the emitter 702 and sub collector 710, and may be less than, equal to, or greater than the concentration of either the base 704 or the base contact region(s) 708, 808. The collector 906 is likely to have a concentration in the range 10¹⁷-10¹⁹ cm⁻³. The connecting base region(s) 712, 812 contact(s) the base 704 and collector 906, but no longer contact(s) the sub collector 710.

This embodiment preserves the advantage resulting from the removal of the direct contact between the connecting base region(s) 712, 812 and the emitter 702. In addition, the reduced doping concentration of the collector 906 relative to the sub collector 710 results in reduced electric field strength in the base 704, and greater immunity to undesirable hot carrier effects.

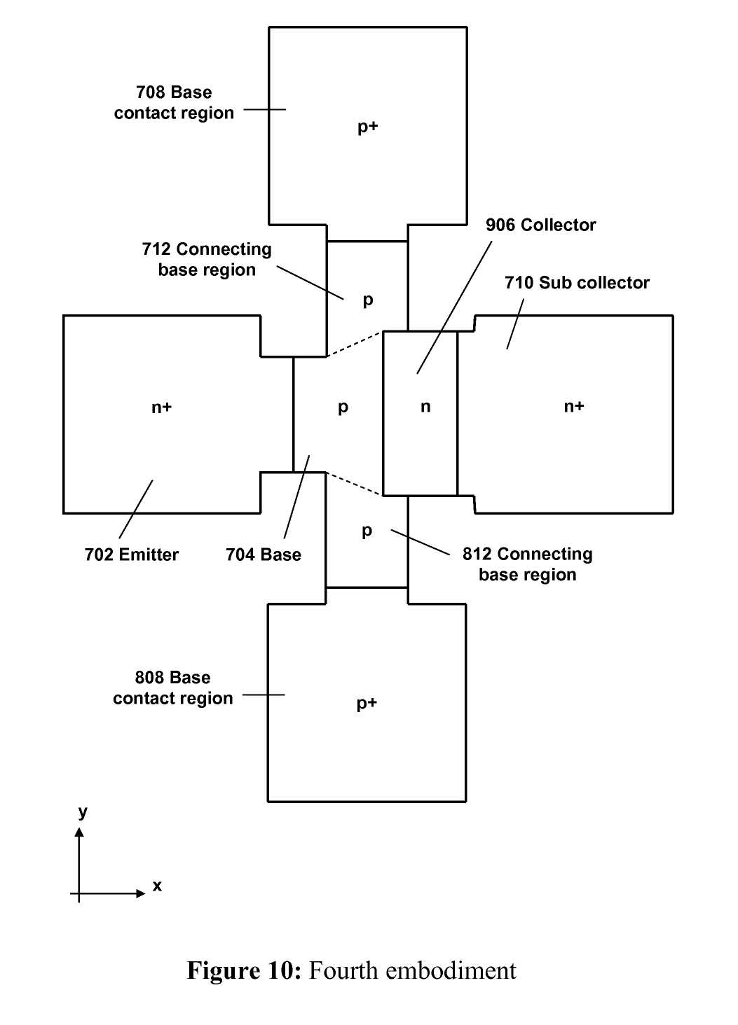

FIG. 10 illustrates a fourth embodiment of the invention. In this embodiment, the BJT is formed as described in any of the first three embodiments, but the width of the sub collector 710 or collector 906 (if present) adjacent the base 704 is increased relative to the emitter 702. As will be appreciated, the width of the sub collector/collector and emitter is with reference to the direction perpendicular to the axis between the emitter and sub collector/collector (i.e., along the y-axis in FIG. 10).

This embodiment retains the advantages of previous embodiments, but the increased width of the collector 906 and/or sub collector 710 reduces the series resistance associated with this/these regions(s). The increased width improves the collection efficiency of charge carriers originating from the emitter 702. This increases the efficiency of the BJT and improves performance.

The BJT may be fabricated in a manner that is compatible with typical TFT fabrication processes. A thin film of semiconductor is deposited on an insulating substrate and a photoresist is spun-on and patterned by lithography. After developing the resist, exposed semiconductor is removed by etching to leave a semiconductor island 701 of the desired shape and the remaining resist is removed. The entire semiconductor island 701 may then be doped by ion implantation to the level desired for the base 704 and connecting base region 712. The emitter 702 and sub collector 710 are formed by again spinning on resist and patterning it by lithography so that only the emitter 702 and sub collector 710 are exposed following development. A further ion implantation step is then carried out, with opposite conductivity type and a significantly higher concentration to that used for the base 704 and connecting base region 712. Only the emitter 702 and sub collector 712 receive this dose. If the emitter 702 and sub collector 712 are to have different doping concentrations then two separate patterning and implantation steps must be used. Following ion implantation the remaining resist is removed and the procedure of patterning resist and implantation is repeated for the base contact region 708, although in this case a dopant with the same conductivity type as the base 704 is used (at higher dose). If a collector 906 is utilized, then additional resist patterning and implantation steps are required.

Following all implantation steps, the device is furnace annealed to activate the dopants. Typically this is performed at the maximum temperature that the substrate can withstand, although techniques such as laser annealing may also be used. A metallisation process then follows, which typically involves depositing a layer of insulator such as SiO₂ or SiNₓ and opening holes to the emitter 702, sub collector 710 and base contact region 708 by patterning and etching, followed by deposition of metal such as Ti, Al or TaN. The metal may then be patterned as required to form electrical connections between devices.

It will be noted that in the various embodiments of the invention as described herein the connecting base region incurs some direct contact with the sub collector or collector in addition to the base. However, those having ordinary skill with appreciate that there is no need for the connecting base region to contact both the base and sub collector/collector. On the other hand, it is preferable that the connecting base region contact the base region right up to the boundary with the sub collector/collector. In practice, there will be small shifts of the doped areas relative to the semiconductor island due to manufacturing alignment errors. To ensure that the connecting base region covers the base region right up to the collector it is designed with some overlap of the collector, so that even if there is a mask shift, the BJT will still operate as expected.

Further, it is noted that the various embodiments of the invention as described herein include a sub collector and in some embodiments both a sub collector and a collector. It will be appreciated, however, that the invention also includes embodiments in which the BJT includes only a collector.

Although the invention has been shown and described with respect to a certain embodiment or embodiments, equivalent alterations and modifications may occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein exemplary embodiment or embodiments of the invention. In addition, while a particular feature of the invention may have been described above with respect to only one or more of several embodiments, such feature may be combined with one or more other features of the other embodiments, as may be desired and advantageous for any given or particular application.

### INDUSTRIAL APPLICABILITY

The bipolar junction transistor of the present invention provides increased DC gain and efficiency, with improved performance for analogue applications. At the same time, the transistor can be fabricated in a conventional TFT process flow without any additional complexity.

1. A bipolar junction transistor, comprising:
a semiconductor island on an insulating substrate;
an emitter and at least one of a collector and sub collector within the semiconductor island, the emitter and the at least one of the collector and the sub collector being of a first conductivity type;
a base within the semiconductor island separating the emitter and the at least one of the collector and the sub collector, the base being of a second conductivity type;
a base contact region within the semiconductor island, the base contact region being of the second conductivity type; and
a connecting base region adjacent the base within the semiconductor island and connecting the base to the base contact region while not directly contacting the emitter, the connecting base region being of the second conductivity type with a doping concentration less than a doping concentration of the base contact region.

2. The bipolar junction transistor according to claim 1, wherein the base and the connecting base region have an equal doping concentration.

3. The bipolar junction transistor according to claim 1, including the sub collector and wherein the sub collector has a doping concentration greater than a doping concentration of the base and equal to a doping concentration of the emitter.

4. The bipolar junction transistor according to claim 1, wherein the connecting base region does not directly contact the at least one of the collector and the sub collector.

5. The bipolar junction transistor according to claim 1, wherein the connecting base region does directly contact the at least one of the collector and the sub collector.

6. The bipolar junction transistor according to claim 1, further comprising a second base contact region and a second connecting base region adjacent the base within the semiconductor island, and wherein the second connecting base region connects the base to the second base contact region while not directly contacting the emitter.

7. The bipolar junction transistor according to claim 6, wherein the base contact region and the second base contact region are adjacent opposite sides of the base.

8. The bipolar junction transistor according to claim 1, including the collector and the sub collector with the collector being positioned between the base and the sub collector, and wherein a doping concentration of the collector is less than a doping concentration of the emitter and a doping concentration of the sub collector.

9. The bipolar junction transistor according to claim 8, wherein the connecting base region does not contact the sub collector.

10. The bipolar junction transistor according to claim 1, wherein a width of the at least one of the collector and the sub collector adjacent the base is greater than a corresponding width of the emitter.

11. The bipolar junction transistor according to claim 1, wherein the first conductivity type is n-type and the second conductivity type is p-type.

12. The bipolar junction transistor according to claim 1, wherein the first conductivity type is p-type and the second conductivity type is n-type.

13. The bipolar junction transistor according to claim 1, wherein a doping concentration of the base contact region is at least an order of magnitude higher than a doping concentration of the connecting base region.

14. The bipolar junction transistor according to claim 1, wherein the semiconductor island comprises a thin film semiconductor.
